(19) United States
(12) Patent Application Publication
(10) Pub. No.: US 2008/0233742 A1
(43) Pub. Date: Sep. 25, 2008

(54) METHOD OF DEPOSITING ALUMINUM LAYER AND METHOD OF FORMING CONTACT OF SEMICONDUCTOR DEVICE USING THE SAME

(75) Inventors: Choon Hwan KIM, Seongnam-si (KR); II Cheol Rho, Icheon-si (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hynix Semiconductor Inc., Icheon-si (KR)

(21) Appl. No.: 11/951,243

(22) Filed: Dec. 5, 2007

(30) Foreign Application Priority Data
Mar. 23, 2007 (KR) 10-2007-0028626

(51) Int. Cl. H01L 21/44

(52) U.S. Cl. 438/675; 438/688; 257/E21.476

(57) ABSTRACT

A contact hole is formed in an interlayer insulating layer disposed on a semiconductor substrate. The semiconductor substrate is loaded into a reaction chamber. A reaction gas including an aluminum precursor is injected into the reaction chamber. Reaction energy is supplied to the reaction chamber so as to allow thermal decomposition of the aluminum precursor. The injecting of the reaction gas and the supplying of the reaction energy are periodically repeated to deposit a first aluminum layer on the semiconductor substrate. A second aluminum layer is deposited to fill the contact hole.

### CROSS-REFERENCE TO RELATED APPLICATIONS

The present application claims priority to Korean patent application number 10-2007-0028626, filed on Mar. 23, 2007, which is incorporated by reference in its entirety.

### BACKGROUND OF THE INVENTION

The present invention relates to a method of fabricating a semiconductor device, and more particularly, to a method of forming a contact plug using an aluminum layer and an aluminum layer deposition method for improving the characteristics of the semiconductor device by reliably filling a contact hole.

As the minimum feature size of semiconductor devices decreases, it becomes more difficult to fill contact holes or via holes which affects the operating speed of contact resistors or the semiconductor devices. Therefore, a process for uniformly filling the contact holes or via holes is important. Usually, tungsten (W) is used to fill contact holes for forming contact plugs in the contact holes. However, contact plugs using tungsten (W) requires a complicated process, and the resistivity of tungsten (W) is greater than that of aluminum (Al).

For this reason, much research has been conducted on aluminum-plug processes for filling contact holes using a wetting layer formed by depositing aluminum (Al) by chemical vapor deposition (CVD). However, when the aluminum-plug process is used for filling small-sized contact holes, overhangs can occur at inlets of the contact holes during physical vapor deposition (PVD) of aluminum (Al) and heat treatment of the PVD aluminum (Al) due to defective step coverage characteristics of a CVD aluminum layer used as the wetting layer. Therefore, a deposition process for forming a conformal aluminum layer without overhangs at the inlets of contact holes is needed.

Generally, a thin aluminum layer can be uniformly formed, and the step coverage characteristics of the aluminum layer can be improved when the aluminum layer is formed by atomic layer deposition (ALD) using two gases in turns. However, the ALD cannot be used for an AlH₃ based precursor since the AlH₃ based precursor is deposited by thermal decomposition using a single gas supply.

### SUMMARY OF THE INVENTION

Embodiments of the present invention are directed to a method of depositing an aluminum layer and a method of forming a contact of a semiconductor device using the aluminum layer deposition method, for improving the characteristics of the semiconductor device by reliably filling a contact hole.

In one embodiment, there is provided a method of depositing an aluminum layer. In the method, a semiconductor substrate is loaded into a reaction chamber. A reaction gas including an aluminum precursor is injected into the reaction chamber. Reaction energy is supplied to the reaction chamber so as to allow thermal decomposition of the aluminum precursor. The injecting of the reaction gas and the supplying of the reaction energy are periodically repeated to deposit an aluminum layer on the semiconductor substrate.

The injecting of the reaction gas may be performed while maintaining the semiconductor substrate at room temperature.

The supplying of the reaction energy may be performed using ultra violet (UV) light, plasma or infrared (IR) lamp, or through a rapid thermal process (RTP). In the case of using plasma, the supplying of the reaction energy may be performed in a hydrogen (H₂) gas atmosphere.

In another embodiment, there is provided a method of forming a contact of a semiconductor device. In the method, a contact hole is formed in an interlayer insulating layer formed on a semiconductor substrate, and the semiconductor substrate is loaded into a reaction chamber. A reaction gas including an aluminum precursor is injected into the reaction chamber, and reaction energy is supplied to the reaction chamber so as to allow thermal decomposition of the aluminum precursor. The injecting of the reaction gas and the supplying of the reaction energy are periodically repeated to deposit a first aluminum layer on the semiconductor substrate. A second aluminum layer is deposited to fill the contact hole.

The injecting of the reaction gas may be performed while maintaining the semiconductor substrate at room temperature.

The supplying of the reaction energy may be performed using UV light, plasma or IR lamp, or through a rapid thermal process (RTP). In the case of using plasma, the supplying of the reaction energy may be performed in a hydrogen (H₂) gas atmosphere.

The second aluminum layer may be deposited by physical vapor deposition (PVD).

After the depositing of the second aluminum layer, the method may further include heat-treating the semiconductor substrate on which the second aluminum layer is deposited so as to allow the second aluminum layer to reflow.

### BRIEF DESCRIPTION OF THE DRAWINGS

FIGS. 1A and 1B illustrate examples of precursors for depositing a thin aluminum layer.

FIGS. 2 and 3 illustrate a method of depositing a thin aluminum layer on a semiconductor substrate using a TMAAB precursor.

FIGS. 4 to 6 illustrate a method of forming contact plugs in a semiconductor device according to one embodiment of the present invention.

### DESCRIPTION OF SPECIFIC EMBODIMENTS

An aluminum compound called a precursor is used as a raw material for depositing a thin aluminum layer by chemical vapor deposition (CVD). When a thin metal layer is deposited, the characteristics of a precursor have a significant influence on the resulting thin metal layer, and thus selection of the precursor is very important. In a current process for filling contact holes of a semiconductor device, an AlH₃ based aluminum precursor is frequently used to form a thin aluminum layer by CVD. The deposition mechanism of a thin aluminum layer is thermal decomposition. In detail, after an AlH₃ based precursor is absorbed in a semiconductor substrate in the temperature range from 150° C. to 200° C., a thin aluminum layer is deposited as Al—N bonds and Al—H bonds are separated.

In the present invention, AlH₃ based gas is applied to a semiconductor substrate while maintaining the temperature of the semiconductor substrate at room temperature to attach molecules of an AlH₃ based precursor to the surface of the semiconductor substrate, and then the semiconductor substrate is processed using ultra violet (UV) light or plasma to supply reaction energy to the AlH₃ based precursor for thermal decomposition of the AlH₃ based precursor. Here, a thin layer deposited on the semiconductor substrate by the decomposed AlH₃ based precursor can have improved step coverage characteristics by alternately supplying the AlH₃ based gas and the reaction energy to the semiconductor substrate.

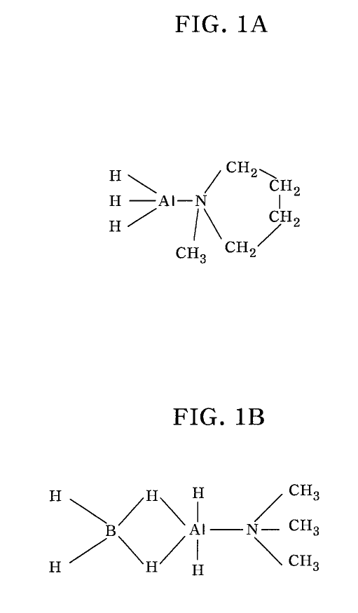

FIGS. 1A and 1B illustrate examples of precursors for depositing a thin aluminum layer. FIG. 1A illustrates the structural formula of methylpyrrolidine alane (C₅H₁₄AlN, hereinafter, referred to as MPA), and FIG. 1B illustrates the structural formula of trimethylaminealane borane (C₃H₁₅AlBN, hereinafter, referred to as TMAAB).

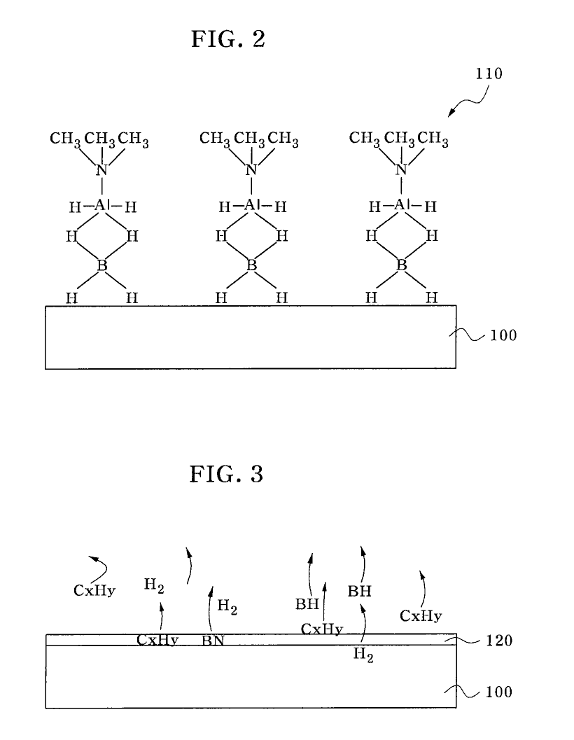

Referring to FIGS. 1 and 2, each of the MPA and the TMAAB has an AlH₃ group having three hydrogen (H) atoms and one aluminum (Al) atom. Since such an AlH₃ based compound does not include an aluminum (Al)-carbon (C) bond, a thin aluminum layer deposited using the AlH₃ based precursor has an advantageous low carbon content. Particularly, since hydrogen (H) atoms of the AlH₃ group are coupled with a boron (B) in the TMAAB, a thin aluminum layer deposited using the TMAAB can have good gas stability with respect to temperature and time.

FIGS. 2 and 3 illustrate a method of depositing a thin aluminum layer on a semiconductor substrate using a TMAAB precursor.

Referring to FIG. 2, a semiconductor substrate 100 is loaded in a reaction chamber. When a reaction gas including an AlH₃ based precursor 110 is injected into the reaction chamber, molecules of the AlH₃ based precursor 110 are attached to the surface of the semiconductor substrate. Here, the semiconductor substrate 100 is kept at room temperature to prevent thermal decomposition of the AlH₃ based precursor 110.

Instead of using the MPA or the TMAAB illustrated in FIGS. 1A and 1B as the AlH₃ based precursor 110 for depositing a thin aluminum layer, demethylethylamine alane (C₄H₁₄AlN, hereinafter, referred to as DMEAA) or other AlH₃ based precursors can be used as the AlH₃ based precursor 110.

Referring to FIG. 3, after the AlH₃ based precursor 110 is absorbed in the surface of the semiconductor substrate 100, reaction energy can be supplied to the semiconductor substrate 100 for thermally decomposition of the AlH₃ based precursor 110, thereby forming an aluminum layer 120 on the semiconductor substrate 100. The aluminum layer 120 can be uniformly formed by periodically repeating the injection of the reaction gas including the AlH₃ based precursor 110 and the supply of the reaction energy.

The reaction energy for thermal decomposition of the AlH₃ based precursor 110 can be supplied to the semiconductor substrate 100 using UV light, plasma, a rapid thermal process (RTP), or an infrared (IR) lamp. In the case of using plasma as a reaction energy source, the semiconductor substrate 100 can be processed in a hydrogen gas (H₂) atmosphere to facilitate the thermal decomposition of the AlH₃ based precursor 110.

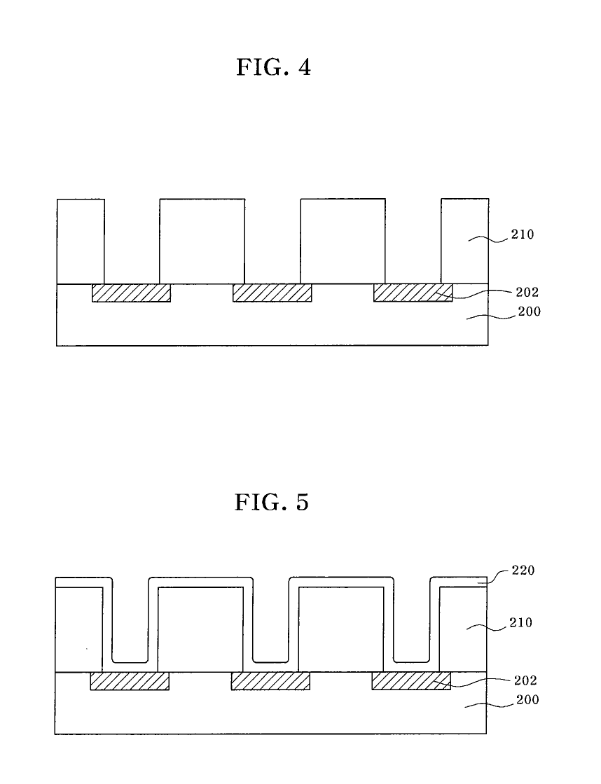

FIGS. 4 to 6 illustrate a method of forming contacts in a semiconductor device according to one embodiment of the present invention.

Referring to FIG. 4, an insulating layer such as an oxide layer is deposited on a semiconductor substrate 200 as an interlayer insulating layer 210. Although not shown for conciseness, the semiconductor substrate 200 may include a bottom structure including bit lines and transistors having source/drain regions.

Next, a photolithograph process is performed to etch the interlayer insulating layer 210 to form contact holes through which a lower conductive layer 202 is exposed. The lower conductive layer 202 may be source/drain regions of the transistors or the wiring layers such as bit lines.

Referring to FIG. 5, an aluminum wetting layer 220 is deposited on the semiconductor substrate 200 including the contact holes by CVD. Here, an AlH₃ based compound such as MPA, TMAAB, or DMEAA is used as a precursor for the aluminum wetting layer 220.

In detail, a reaction gas including an AlH₃ based precursor is injected to a reaction chamber in which the semiconductor substrate 200 is loaded to attach molecules of the AlH₃ based precursor to the surface of the semiconductor substrate 200. Here, the semiconductor substrate 200 is kept at room temperature to prevent thermal decomposition of the AlH₃ based precursor. Next, the temperature of the reaction chamber is increased to a temperature of about 300° C. to 450° C. to supply reaction energy to the AlH₃ based precursor. Then, aluminum (Al)-nitrogen (N) bonds and aluminum (Al)-hydrogen (H) bonds of the AlH₃ based precursor are broken by thermal decomposition, and thus the aluminum wetting layer 220 can be deposited on the semiconductor substrate 200.

The aluminum wetting layer 220 can be uniformly grown by periodically repeating the injection of the reaction gas including the AlH₃ based precursor and the supply of the reaction energy.

The temperature of the reaction chamber can be increased using UV light, plasma, an RTP, or an IR lamp. In the case of using plasma to increase the temperature of the reaction chamber, the semiconductor substrate 200 can be processed in a hydrogen gas (H₂) atmosphere to facilitate the thermal decomposition of the AlH₃ based precursor.

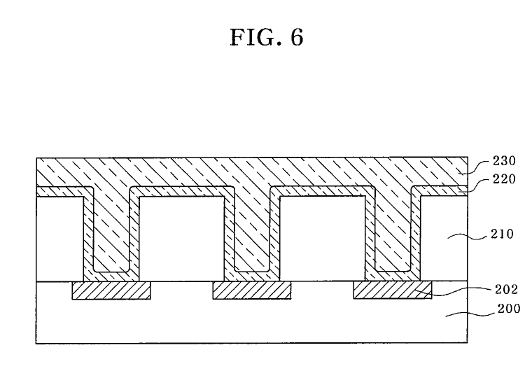

Referring to FIG. 6, an aluminum layer 230 is deposited on the aluminum wetting layer 220 by physical vapor deposition (PVD) to fill the contact holes. The PVD aluminum layer 230 can be deposited in-situ in the reaction chamber after the aluminum wetting layer 220 is deposited in the reaction chamber.

After the PVD aluminum layer 230 is deposited, in-situ heat treatment is performed to allow the deposited PVD aluminum layer 230 to reflow so as to improve contact hole filling characteristics.

As described above, in the method of depositing an aluminum layer according to the present invention, the injection of a reaction gas including an AlH₃ based precursor and the supply of reaction energy are alternately repeated. Therefore, a conformal CVD aluminum layer can be formed.

Furthermore, after a conformal aluminum wetting layer is deposited on a semiconductor substrate where contact holes are formed by using an AlH₃ based compound as a precursor of the aluminum wetting layer, the contact holes are filled by PVD so that the contact holes can be filled without voids. Therefore, reliable contacts and interconnection lines can be formed in a semiconductor device, and detects of the semiconductor can be reduced. Thus, the manufacturing costs of the semiconductor device can be reduced.

The embodiments of the present invention have been disclosed above for illustrative purposes. Those skilled in the art will appreciate that various modifications, additions and substitutions are possible, without departing from the scope and spirit of the invention as disclosed in the accompanying claims.

What is claimed is:

1. A method of depositing an aluminum layer, the method comprising:
loading a semiconductor substrate into a reaction chamber; and
injecting a reaction gas comprising an aluminum precursor into the reaction chamber; and
supplying reaction energy to the reaction chamber so as to allow thermal decomposition of the aluminum precursor,
wherein the injecting of the reaction gas and the supplying of the reaction energy are periodically repeated to deposit an aluminum layer on the semiconductor substrate.

2. The method of claim 1, wherein the injecting of the reaction gas is performed while maintaining the semiconductor substrate at room temperature.

3. The method of claim 1, wherein the supplying of the reaction energy is performed using ultra violet (UV) light, plasma, or infrared (IR) light, or through a rapid thermal process (RTP), or a combination thereof.

4. The method of claim 3, wherein the supplying of the reaction energy is performed using plasma in an environment including hydrogen (H₂) gas.

5. A method of forming a contact plug of a semiconductor device, the method comprising:
forming a contact hole in an insulating layer formed over a semiconductor substrate;
depositing a first aluminum layer over the semiconductor substrate and the insulating layer after the contact hole has been formed, the first aluminum layer defining a conformal layer within the contact hole; and
depositing a second aluminum layer over the first aluminum layer, the second aluminum layer at least substantially filing the contact hole,
wherein the depositing of the first aluminum layer comprises:
injecting a reaction gas comprising an aluminum precursor into a reaction chamber in which the semiconductor substrate is loaded; and
supplying reaction energy to the reaction chamber so as to allow thermal decomposition of the aluminum precursor,
wherein the injecting of the reaction gas and the supplying of the reaction energy are periodically repeated to deposit the first aluminum layer on the semiconductor substrate.

6. The method of claim 5, wherein the injecting of the reaction gas is performed while maintaining the semiconductor substrate at room temperature.

7. The method of claim 5, wherein the supplying of the reaction energy is performed using UV light, plasma, or IR light, or through a rapid thermal process (RTP), or a combination thereof.

8. The method of claim 7, wherein the supplying of the reaction energy is performed using plasma in an environment including hydrogen (H₂) gas.

9. The method of claim 5, wherein the second aluminum layer is deposited by physical vapor deposition (PVD).

10. The method of claim 5, wherein after the depositing of the second aluminum layer, the method further comprises heat-treating the semiconductor substrate having the second aluminum layer to cause the second aluminum layer to reflow.
